(19) United States
(12) Patent Application Publication
(10) Pub. No.: US 2026/0231841 A1
(43) Pub. Date: Aug. 6, 2026

(54) Low Resistance Hybrid Bonded Interconnects

(71) Applicant: Applied Materials, Inc., Santa Clara, CA (US)

(72) Inventors: Kevin RYAN, Albany, NY (US); Qian GE, Clifton Park, NY (US); Scott Alexander DEVRIES, Albany, NY (US); Raghav SREENIVASAN, Santa Clara, CA (US)

(21) Appl. No.: 19/046,785

(22) Filed: Feb. 6, 2025

(51) Int. Cl. H01L 23/00

(52) U.S. Cl. CPC H10W 99/00; H10W 72/019; H10W 72/90; H10W 72/01935; H10W 72/01938; H10W 72/01951; H10W 72/923; H10W 72/934; H10W 72/952; H10W 80/312; H10W 80/327; H10W 90/792

(57) ABSTRACT

Methods for reducing the resistance of a contact leverage fine grain sizes to increase thermal expansion during hybrid bonding for increased bonding strength and fine grain growth after bonding to decrease resistance of the contact. In some embodiments, the method may comprise bonding a first contact on a first substrate to a second contact on a second substrate where a first end region of the first contact has a bonding surface and has a first average grain size that is smaller than a second average grain size of a second end region that is opposite of the first end region and where the first end region has grain boundary pinning additives in the first end region and driving the additives from the first end region to the second end region after bonding using a thermal treatment to promote grain growth within the first end region.

### FIELD

Embodiments of the present principles generally relate to semiconductor processing of semiconductor substrates.

### BACKGROUND

In hybrid bonding, a combination of dielectric and conductive materials are bonded to each other, in a single bonding process. The conductive materials used in contacts form interconnects when bonded and thermally annealed that provide signal or power to devices on a substrate or die. As the density of the contacts continues to increase, the contacts become smaller with reduced widths and increased aspect ratios. The inventors have observed that as the contact size diminishes, the expansion of the conductive material during hybrid bonding also decreases, causing improper connections during bonding and annealing which results in poor electrical yields.

Accordingly, the inventors have provided improved hybrid bonding processes that substantially increase bonding yields while reducing resistance of contacts which increases overall device performance.

### SUMMARY

Methods and structures for reducing contact resistance for hybrid bonding are provided herein.

In some embodiments, a method for reducing resistance of a contact may comprise depositing a first end region of a first contact in an opening of a first substrate where the first end region is formed of a first conductive material with a first average grain size and depositing a second end region on the first end region of the first contact where the second end region is a second conductive material which is deposited with a second average grain size smaller than the first average grain size.

In some embodiments, the method may further include a first end region that is deposited using a physical vapor deposition-based process which incorporates a reflow process and/or an etch back and redeposition process to deposit the first conductive material, a second end region that is deposited using an electrochemical plating deposition process with grain boundary pinning additives in a plating bath to deposit the second conductive material embedded with grain boundary pinning additives, an anneal process that is performed after depositing the second end region, a chemical mechanical (CMP) planarization process that is performed to form a recess on a bonding surface of the second end region where the bonding surface is distal to the second end region, a second average grain size that is less than approximately 10 nm, a height of the first end region of the first contact that is approximately 20% to approximately 60% of a contact height of the first contact, a second conductive material that has a coefficient of thermal expansion (CTE) greater than the first conductive material, a second conductive material that has a surface mobility higher than the first conductive material, bonding the first substrate to a second substrate to form a bonded substrate where the first contact is aligned with a second contact in the second substrate forming a recess between uppermost surfaces of the first contact and the second contact and annealing the bonded substrate to drive grain boundary pinning additives embedded in the second end region into the first end region using a thermal treatment to promote grain growth within the first end region where the thermal treatment is performed at a temperature of approximately 450 degrees Celsius or less for a duration of approximately five minutes or less and annealing to cause expansion of second end regions of the first contact and the second contact until the first contact and the second contact are bonded, a grain growth within the second end region after the thermal treatment that is approximately 100% or more, and/or a first conductive material and the second conductive material comprise copper.

In some embodiments, a contact for hybrid bonding may comprise a first end region of the contact with a first conductive material with a first average grain size and a second end region of the contact with a second conductive material with a second average grain size smaller than the first average grain size of the first conductive material and formed on the first conductive material where the second end region has a bonding surface and contains grain boundary pinning additives.

In some embodiments, the contact may further include a bonding surface of the first end region is approximately 1 nm to approximately 5 nm below surrounding surfaces of a substrate in which the contact is formed, a first end region is approximately 20% to approximately 60% of a height of the contact, grain boundary pinning additives that include aromatic compounds, grain boundary pinning additives that include suppressor molecules, a second average grain size that is less than approximately 5 nm, and/or a second end region that has a coefficient of thermal expansion (CTE) greater than the first end region.

In some embodiments, a non-transitory, computer readable medium having instructions stored thereon that, when executed, cause a method for reducing resistance of a contact to be performed, the method may comprise depositing a first end region of a first contact in an opening of a first substrate where the first end region is formed of a first conductive material with a first average grain size and depositing a second end region on the first end region of the first contact where the second end region is a second conductive material which is deposited with a second average grain size smaller than the first average grain size.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of reducing resistance of a contact in accordance with some embodiments of the present principles.

FIG. 2 depicts a cross-sectional view of a contact in a substrate or die with a first conductive material in accordance with some embodiments of the present principles.

FIG. 3 depicts a cross-sectional view of a contact in a substrate with a first conductive material and a second conductive material in accordance with some embodiments of the present principles.

FIG. 4 depicts a cross-sectional view of a contact in a substrate after a chemical mechanical planarization process in accordance with some embodiments of the present principles.

FIG. 5 depicts a cross-sectional view of contacts after a hybrid bonding process in accordance with some embodiments of the present principles.

FIG. 6 depicts a cross-sectional view of a bonded contact or interconnect after a rapid thermal anneal process in accordance with some embodiments of the present principles.

FIG. 7 depicts a graph denoting thermal budgets for post bond anneals in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide higher hybrid bonding yields while reducing the resistance of bonded contacts. The reduced contact resistance may provide overall device performance increases of approximately 0.5% or greater. The present techniques are especially beneficial for high aspect ratio contacts (e.g., sub 500 nm pitches) where the smaller widths interfere with the expansion of the conductive material during bonding, causing electrical connection failures. Fine grains are used in a bonding region of the contact to increase both the coefficient of thermal expansion (CTE) and surface mobility to ensure full bonding of the contact between bonded substrates and/or dies and the like. A subsequent rapid thermal anneal process increases the growth of the fine grains in the bonding region to reduce the resistance of the bonded contact.

As the pitch of copper hybrid bonding is aggressively scaled, the challenges of forming high quality metal connections after bonding becomes more difficult because of reductions in the copper expansion during the post bond anneal. A fine grain copper process can enable greater expansion of the copper but comes with a contact resistance penalty in the final interconnect system. By combining fine grain copper in a bonding region combined with reflow and/or physical vapor deposition (PVD) copper seed processes in a lower region of a contact followed by a post bond rapid thermal anneal, the resistance penalty from fine grain copper can be mitigated. The lower region of the contact is filled with large grain copper by a PVD deposition/etch back process and/or a PVD/reflow deposition process followed by an upper region or bonding region filled with fine copper grains by an electrochemical plating (ECP) process with grain boundary pinning additives. Hybrid bonding is then performed followed by a rapid thermal anneal process that expands the copper to form an interconnection. The rapid thermal anneal process causes an increase in the size of the fine copper grains in the upper region of the contact by driving the grain boundary pinning additives into the lower region due to the concentration gradient. In some embodiments, copper is deposited in a contact via in the lower region using a copper PVD/reflow deposition and/or a copper PVD deposition with an etch back process to fill the contact up to approximately 60% in height with larger grain copper. The remaining portion or upper region is filled with fine grain copper that includes the grain boundary pinning additives which is then planarized to form a bonding recess in the fine grain copper.

The fine grain structure at the top of the contact via increases the copper mobility and limits the (111) grain orientation of the copper at the bonding interface. The (111) grain orientation has the lowest expansion rate and results in a lower quality bond (voids, defects, etc.). Reducing the (111) grain orientation promotes greater copper expansion during hybrid bonding, producing higher yields for copper interconnections. During the post bonding high temperature anneal of the present techniques, the pure copper at the contact via bottom (lower region) acts as an additive sink due to the concentration gradient of the additives. The additive mobility in the pure copper region during the annealing reduces the grain boundary pinning effect in the upper region and promotes reorientation and grain growth in the fine grain copper of the upper region, even without overburden present. The combined effect of the present techniques improves hybrid bonding yields at equivalent post bond alignment regimes and lowers the total resistance of the system due to grain reorientation and growth at the copper interconnect interface (bonding interface).

The fine grain copper deposition uses electrochemical plating to deposit the copper onto the substrate and into the contact, filling the contact and forming overburden on the substrate. The fine grain copper in the upper region has a higher CTE and surface mobility than the copper deposited in the lower region by the PVD/reflow and/or PVD/etch back deposition processes. The higher CTE and surface mobility enables the copper in the upper region to have greater expansion within the contact during a post bond anneal that ensures a good copper-to-copper bonded contact. The post bond anneal is a rapid thermal anneal process using a temperature of approximately 450 degrees Celsius or less for approximately 5 minutes or less. In some embodiments, the flash or rapid thermal anneal is approximately 2 minutes or less. The rapid thermal anneal process drives the grain boundary pinning additives used to maintain the fine grain copper into the large grain lower region during the rapid thermal anneal expansion, allowing the fine grain copper to grow in size, reducing the contact resistance at the bonding interface. In addition, with fewer additives pinning the grain boundaries, the opportunity for grain reorientation is increased which creates a higher yielding and lower resistance connection than with fine grain copper alone.

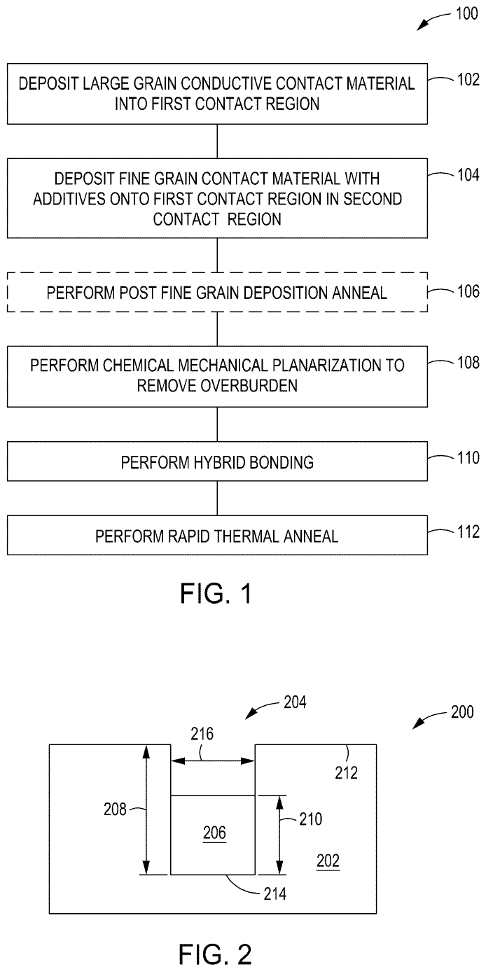

FIG. 1 is a method 100 for reducing contact resistance for a hybrid bonded interconnect. In block 102, a first conductive material 206 with large grains and no additives is deposited into an opening or contact 204 of a substrate 202 as depicted in a view 200 of FIG. 2. The average grain size of the first conductive material may be based on a feature size or parameter such as, for example, the diameter 216 of the opening or contact 204. In some embodiments, the average grain size of the first conductive material 206 may be approximately 100% of the diameter 216 of the opening or contact 204. In some embodiments, the average grain size of the first conductive material 206 may be approximately 60% or greater of the feature size. A liner barrier metal layer may be deposited into the opening or contact 204 prior to the deposition of the first conductive material 206. In some embodiments, the liner barrier metal layer is a TaN/Ta liner barrier layer. Although the substrate 202 is depicted in the figures, the opening or contact 204 may also be formed in a die and the like. A substrate is used in the examples for the sake of brevity. The first conductive material 206 has no grain boundary pinning additives. In some embodiments, the first conductive material 206 may be pure copper (e.g., 99.9995% or higher copper purity, etc.). The total height 208 of the contact 204 is measured from a bottom 214 of the contact 204 to an upper surface 212 of the substrate 202. The fill height 210 of the first conductive material 206 is approximately 20% to approximately 60% of the total height 208 of the contact 204. The first conductive material 206 may be deposited using a PVD process in conjunction with a reflow process and/or a PVD process in conjunction with an etch back process. In some embodiments, multiple cycles of deposition and/or reflow or etch back may be used to reach the fill height 210 of the first conductive material 206. During the PVD processes, an etch back process may be used to ensure that overhangs do not pinch off the openings so that subsequent deposition cycles can deposit more material inside of the openings. The PVD filling techniques provide large grain, low resistance conductive material into the contact 204. The large grains result in fewer grain boundaries which results in lower resistance. The PVD processes come with a cost as filling contact vias using PVD is time consuming due to the many cycles needed to fill the contact 204. As such, adjusting the fill height 210 may be based on throughput and/or cost concerns. The lower the fill height 210, the lower the cost and the higher the throughput. A 20% fill height is faster and cheaper than a 60% fill height for the first conductive material 206. However, a contact filled with a 60% fill height will produce a contact with an overall lower resistance. Thus, a tradeoff exists between throughput and performance when determining the amount of fill height used for the first conductive material 206.

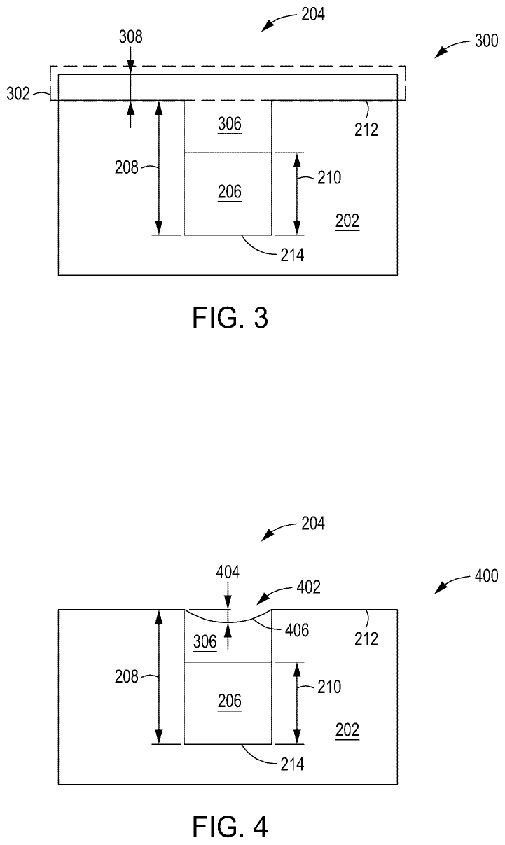

In block 104, a second conductive material 306 with fine grains and embedded grain boundary pinning additives is deposited into the opening or contact 204 of the substrate 202 and onto the upper surface 212 of the substrate 202 as depicted in a view 300 of FIG. 3. In some embodiments, the second conductive material 306 may be copper. In some embodiments, the average grain size of the second conductive material 306 may be less than approximately 10 nm. In some embodiments, the average grain size of the second conductive material 306 may be less than approximately 5 nm. The second conductive material 306 may be deposited using an ECP process that includes dipping the substrate 202 into a plating bath. The solution of the plating bath additionally contains additives that are used to pin the grain boundaries and create fine grains of the second conductive material 306. A grain boundary pinning additive, as used herein, includes any additives that cause grain sizes in the deposited material in which the additives are embedded to remain substantially constant during deposition and during the contact portion of hybrid bonding.

The grain boundary pinning additives may fall into one or more categories—leveler molecules and/or suppressor molecules. The leveler molecule additives may include aromatic compounds or aromatic ring structures such as, but not limited to, benzene ring structures and/or nitrogen-phosphorous ring structures, and the like. The suppressor molecules may include polyethylene glycol-based carbon chain molecules and the like. In some embodiments, the concentration of leveler and/or suppressor molecules may be 1-10,000 parts per million (PPM) in the plating bath. In some embodiments, the concentration may be varied based on the feature size (e.g., higher concentrations for larger features, etc.). During the ECP process, material is plated over the surface of the substrate in excess of what is required to fill the opening or contact 204. The excess second conductive material on the substrate 202 is referred to as the overburden 302. In some embodiments, the overburden 302 is at least 1 micron in thickness 308 to enable proper planarization to produce recesses on the bonding surfaces of the contacts prior to hybrid bonding.

In block 106, an optional post fine grain deposition anneal may be performed. In some embodiments, the optional post fine grain deposition anneal may be performed at a temperature of approximately 250 degrees Celsius to approximately 300 degrees Celsius. In general, a post plating anneal such as the post fine grain deposition anneal is performed to help stabilize the grain boundaries of the second conductive material 306 to enhance a subsequent CMP process that removes the overburden 302. During the post plating anneal process, the fine grain size may increase, reducing the surface mobility and CTE of the second conductive material 306. However, the stabilized grain boundaries do provide improved performance repeatability of the planarization of the surface of the second conductive material 306, which increases yields. In some embodiments, the optional post fine grain deposition anneal process is not performed to increase throughput and maintain the grain size of the fine grain deposition. Thus, performing the optional post fine grain deposition anneal process is a tradeoff between CMP performance/yields and maintaining the fine grain sizing for increased thermal expansion and surface mobility (high quality contact and reduced resistance) of the second conductive material 306.

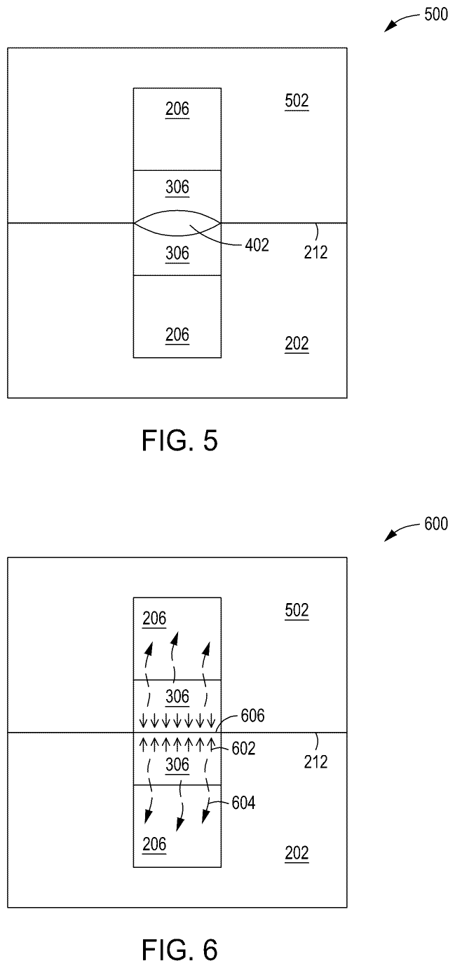

In block 108, a CMP process is performed on the substrate 202 to remove the overburden 302 and to form a recess 402 on a bonding surface 406 of the second conductive material 306 as depicted in a view 400 of FIG. 4. In some embodiments, a depth 404 of the recess 402 may be from approximately 1 nm to approximately 5 nm. The depth 404 of the recess 402 is dependent on the pitch or CD of the contacts. Larger pitches (e.g., 500 nm and larger) will not have conductive material expansion issues. The conductive material expansion issues for hybrid bonding arise when the pitches are reduced below 500 nm, and the issues become more problematic as the pitch decreases. In block 110, a hybrid bonding process is performed. The recess 402 allows for the non-conductive materials on the upper surface 212 of the substrate 202 to come into contact and bond first during the hybrid bonding process with a second substrate 502 as depicted in a view 500 of FIG. 5. In block 112, a rapid thermal anneal process according to the present techniques is performed which expands the second conductive material 306 into the contact interface 606 while driving the grain boundary pinning additives 604 into the first conductive material 206 as depicted in a view 600 of FIG. 6. In some embodiments, the anneal is performed at a temperature of approximately 450 degrees Celsius or less. In some embodiments, the anneal is performed at a temperature of approximately 400 degrees Celsius. In some embodiments, the duration of the anneal is 5 minutes or less. In some embodiments, the duration of the anneal is 2 minutes or less. In some embodiments, the duration of the anneal is 1 minute or less. The duration of the anneal may be based on the amount of grain boundary pinning additive concentrations and/or the distance needed to drive the additives into the large grain region (lower region). The short duration of the rapid thermal anneal keeps the thermal budget of devices on the substrates substantially lower than with traditional post bonding annealing which can last up to an hour or more.

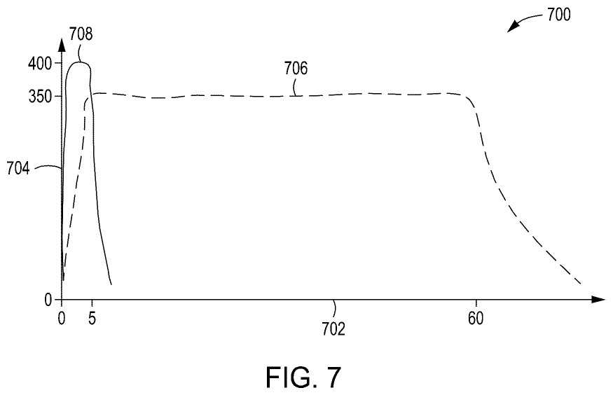

For example, a comparison of thermal budgets for a rapid thermal anneal of the present principles versus a traditional post bond anneal is depicted in a graph 700 of FIG. 7. The X-axis 702 of the graph 700 represents minutes and the Y-axis 704 of the graph 700 denotes degrees Celsius. The area under the dashed line 706 represents the thermal budget for a traditional post bond anneal performed at 350 degrees Celsius for 60 minutes. The area under the solid line 708 represents the thermal budget for the rapid thermal anneal of the present principles performed at approximately 400 degrees Celsius for approximately 5 minutes. Even though the annealing temperature is higher for the rapid thermal anneal, the duration is much shorter. Thus, the thermal budget of the rapid thermal anneal is substantially less than the thermal budget of the traditional post bond anneal. The higher temperature of the rapid thermal anneal is used to provide the energy for the fine grains to expand and bond as well as to drive the grain boundary pinning additives from the fine grain region into the large grain region to allow the fine grains to grow at the bonding interface. This additive diffusion is possible due to the concentration gradient between the fine grain and large grain regions, and the open interstitial sites located within the larger grain boundary interfaces.

The post bond rapid thermal anneal process causes the second conductive material 306 to expand 602 and contact the conductive material of another contact of another substrate or die and fusion bond with that contact, forming an interconnect between the substrates. As the fine grains of the second conductive material 306 are smaller than the large grains of the first conductive material 206, the second conductive material 306 has a higher CTE and surface mobility allowing for greater expansion and better contact with the other contact during bonding, providing a high quality (no voids or defects) and contact interface 606 with a low resistance. The grain boundary pinning additives 604 in the second conductive material 306 are driven into the first conductive material 206 during the rapid thermal anneal process, unpinning the grain boundaries of the second conductive material 306 and allowing for grain growth and grain reorientation of the fine grains of the second conductive material 306, further reducing the resistance of the contact. As the reorientation of the grains occurs, certain orientations will be favored and will dominate and shift other grains to the dominant orientation.

The grains as a whole act as a system during reorientation to find the lowest potential energy point. In some embodiments, the grain growth may be 100% or more due to the rapid thermal anneal process. Larger grains in a given volume have fewer grain boundaries and, thus, less scattering than fine grains in the same volume, yielding lower resistance and higher performance. However, large grains lack the CTE necessary to provide good expansion and high yield bonding in high aspect ratio contact vias compared to fine grains. In some embodiments, the interconnects formed using the present techniques will have a 5 to 10 percent reduction in resistance over contacts using large grains and traditional post bond anneal processes. The reduction in resistance comes from the grain reorientation and the grain growth of the fine grains at the contact interface (the bonding or upper region). The rapid thermal anneal process provides the ability for the grains in the upper region to grow even without overburden present. The present techniques also provide a better bond between contacts due to the high surface mobility and greater thermal expansion during the hybrid bonding process, increasing yields.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for reducing resistance of a contact, comprising:
depositing a first end region of a first contact in an opening of a first substrate, wherein the first end region is formed of a first conductive material with a first average grain size; and
depositing a second end region on the first end region of the first contact, wherein the second end region is a second conductive material which is deposited with a second average grain size smaller than the first average grain size.

2. The method of claim 1, wherein the first end region is deposited using a physical vapor deposition-based process that incorporates a reflow process or an etch back and redeposition process to deposit the first conductive material.

3. The method of claim 1, wherein the second end region is deposited using an electrochemical plating deposition process with grain boundary pinning additives in a plating bath to deposit the second conductive material embedded with grain boundary pinning additives.

4. The method of claim 1, wherein an anneal process is performed after depositing the second end region.

5. The method of claim 1, wherein a chemical mechanical (CMP) planarization process is performed to form a recess on a bonding surface of the second end region, wherein the bonding surface is distal to the second end region.

6. The method of claim 1, wherein the second average grain size is less than approximately 10 nm.

7. The method of claim 1, wherein a height of the first end region of the first contact is approximately 20% to approximately 60% of a contact height of the first contact.

8. The method of claim 1, wherein the second conductive material has a coefficient of thermal expansion (CTE) greater than the first conductive material.

9. The method of claim 1, wherein the second conductive material has a surface mobility higher than the first conductive material.

10. The method of claim 1, further comprising:
bonding the first substrate to a second substrate to form a bonded substrate, wherein the first contact is aligned with a second contact in the second substrate forming a recess between uppermost surfaces of the first contact and the second contact; and
annealing the bonded substrate to drive grain boundary pinning additives embedded in the second end region into the first end region using a thermal treatment to promote grain growth within the first end region, wherein the thermal treatment is performed at a temperature of approximately 450 degrees Celsius or less for a duration of approximately five minutes or less, and wherein annealing causes expansion of second end regions of the first contact and the second contact until the first contact and the second contact are bonded.

11. The method of claim 10, wherein the grain growth within the second end region after the thermal treatment is approximately 100% or more.

12. The method of claim 1, wherein the first conductive material and the second conductive material comprise copper.

13. A contact for hybrid bonding, comprising:
a first end region of the contact with a first conductive material with a first average grain size; and
a second end region of the contact with a second conductive material with a second average grain size smaller than the first average grain size of the first conductive material and formed on the first conductive material, wherein the second end region has a bonding surface and contains grain boundary pinning additives.

14. The contact of claim 13, wherein the bonding surface of the first end region is approximately 1 nm to approximately 5 nm below surrounding surfaces of a substrate in which the contact is formed.

15. The contact of claim 13, wherein the first end region is approximately 20% to approximately 60% of a height of the contact.

16. The contact of claim 13, wherein the grain boundary pinning additives include aromatic compounds.

17. The contact of claim 13, wherein the grain boundary pinning additives include suppressor molecules.

18. The contact of claim 13, wherein the second average grain size is less than approximately 5 nm.

19. The contact of claim 13, wherein the second end region has a coefficient of thermal expansion (CTE) greater than the first end region.

20. A non-transitory, computer readable medium having instructions stored thereon that, when executed, cause a method for reducing resistance of a contact to be performed, the method comprising:
depositing a first end region of a first contact in an opening of a first substrate, wherein the first end region is formed of a first conductive material with a first average grain size; and
depositing a second end region on the first end region of the first contact, wherein the second end region is a second conductive material which is deposited with a second average grain size smaller than the first average grain size.
